(19) United States
(12) Patent Application Publication
(10) Pub. No.: US 2018/0287370 A1
(43) Pub. Date: Oct. 4, 2018

(54) LOW-COST, FULL-RANGE ELECTRONC OVERLOAD RELAY DEVICE

(71) Applicant: James J. Kinsella, Brentwood, TN (US)

(72) Inventor: James J. Kinsella, Brentwood, TN (US)

(21) Appl. No.: 16/003,056

(22) Filed: Jun. 7, 2018

Related U.S. Application Data
(63) Continuation-in-part of application No. 14/037,922, filed on Sep. 26, 2013.

(51) Int. Cl. H02H 7/085; H02H 1/00; H03K 5/24

(52) U.S. Cl. CPC H02H 7/0856; H03K 5/24; H02H 1/0007

(57) ABSTRACT

An electronic overload relay leverages a ratio metric current design to permit size and cost optimized circuit components that can be used to sense current for purposes of protecting motors by detecting overcurrent conditions in branch motor applications in lieu of thermal overload devices. A current divider is used to significantly reduce the current that must be sensed by a magnetically coupled toroid to permit its components to be size and cost optimized and to be implemented easily on a printed circuit board. The DC resistance can be used to provide a coarse design that can be calibrated pre-manufacture to establish the accuracy required in sensing motor load current by adjusting the value of the burden resistor. Precision printed circuit board traces can be used to ensure repeatability during manufacturing. A sweepable trigger value generator can permit operation over the entire range of FLC and the threshold can be calibrated into the device.

### CROSS-REFERENCE TO RELATED APPLICATIONS

This application claims priority as a continuation-in-part of U.S. application Ser. No. 14/037,922, filed Sep. 26, 2013 and titled “RATIO METRIC CURRENT MEASUREMENT,” and which is hereby incorporated herein in its entirety by this reference.

### FIELD OF THE INVENTION

The invention relates to overload protection of motors in motor branch circuits, and more particularly to replacing thermal detection of motor overloads with cost-effective electronic motor overload detection using current sensing.

### BACKGROUND OF THE INVENTION

The AC electric motor is at the core of most industrial commercial processes, and their use is ubiquitous. AC electric motors are typically powered using three-phase AC power that is delivered to each of the motor's three phase coils through one of three branches of a motor branch circuit. AC electric motor branch circuit installations can vary greatly in their physical and parametric characteristics, as a function of their application. These include variations in motor size, required power and the physical layout of the circuit itself.

Various regulatory organizations such as the NEC (National Electricians Code) have promulgated safety detailed precautions/procedures that must be met for all AC motor installations. For example, circuit breakers are required to protect the overall motor branch circuit from short-circuits by interrupting the main system power supply from the motor branch circuit in mid-operation when the magnitude of the current in the circuit exceeds a magnitude that indicates the presence of a short-circuit fault condition. Overcurrent protection of the motor is required for a motor branch circuit. A thermal overload relay protects the motor from drawing load currents that exceed the full load current (FLC) specified for the motor by between 5 and 15%. The NEC requires that an overload relay not trip for load currents below 1.05 times the maximum rated current, and they must trip at no higher than 1.15 times the maximum rated current for the motor.

Those of skill in the art will appreciate that circuit breakers also provide overcurrent protection of circuits by tripping for currents that are below those of a short-circuit, but are deemed an overload of the circuit. However, the overcurrent protection provided by circuit breakers is not suitable for protecting the motor in a motor branch circuit, and is disabled for circuit breakers used in motor branch circuits.

While many industrial applications draw load currents in the hundreds of amps, roughly ninety-five percent of industrial and commercial electric motor applications involve motors of 10 horsepower or less. The maximum specified load current for such motors is 15 amps or less. For such applications where the criticality of the application is not high (i.e. down time and/or motor damage is not as costly), thermal overload protection devices such as bimetallic overload relays are the most commonly deployed device for providing the requisite overload protection in motor branch circuits.

Bimetallic overload relays are a form of heat operated relay where three bimetal strips (one for each phase of the circuit) actuate a trip mechanism in response to being heated by the motor load current flowing therethrough. When the load current is too high for too long, the bimetal strips cause a sliding mechanism to actuate a lever that disconnects the contacts that supply current to the coil of a contactor, thereby causing the contactor to open and disconnect main power to the motor.

While simple and economical, the bimetallic relay can only approximate the thermal characteristic of the motor. Accuracy is further degraded based on differences in the ambient temperature surrounding the relay versus the ambient temperature surrounding the motor itself. Control components such as motor starters, which include the bimetal relay, are typically housed together in large cabinets, where the heat generated by many such devices can cause temperatures inside the cabinet to further degrade accuracy of the relays and cause harm to other motor control components housed therewith. In addition, Bimetallic relays can dissipate as much as 3-5 watts of power per phase as heat. This heat dissipation not only negatively impacts the accuracy of the relays and the health of other proximally located components, but results in a high cost of operation reflected in the excessive waste of energy given the vast number of such motor installations operated throughout the world.

The accuracy limitations of bimetal overload relays make them unsuitable for applications where the results of failure due to overload are very expensive in terms of downtime and replacement of the motor and other components. In addition, as the size of the motor increases and the maximum full load current ratings go up accordingly, considerations of size and heat dissipation requires the use of a transformer with thermal overload relays to first step the current down to a more manageable level for the relay. This only further increases the cost of using bimetal overload relays in such higher current applications.

Most importantly is the fact that a bimetal relay can only operate around a small range of a specified full load current (FLC). For example, over a range of motor sizes having full load current ratings of a few hundreds of milliamps up to about 25 amps, a large number of variants of these devices must be manufactured and inventoried to cover this range of currents. Moreover, if the motor FLC requires a different current range than a currently installed thermal overload relay variant provides, the process of removing and replacing the relay is time consuming and inconvenient.

### SUMMARY OF THE INVENTION

In one aspect of the invention, a ratio metric (RM) electronic overload relay of the invention provides motor overcurrent protection for a motor coupled to a motor branch circuit and employs one or more ratio metric (RM) current sensor assemblies. Each of the (RM) current sensor assemblies is configured to be coupled in series with one of one or more branches of the motor branch circuit to sense motor load current flowing therethrough. Each of the one or more RM sensor assemblies includes a current divider made up of a low impedance conductor configured to be conductively coupled in series with the branch and a higher impedance conductor coupled to two points along the low impedance conductor. The low impedance conductor forms a main path of the current divider between the two points and the higher impedance conductor forms a secondary path of the current divider.

In an embodiment, a current sensor is magnetically coupled to the secondary path of the current divider. The current sensor is a current transformer that includes: 1) a core through which the higher impedance conductor is fed as a primary of the transformer; 2) a secondary that is established through one or more windings of a conductor about the core; and 3) a burden resistor that is coupled to the secondary. The RM current sensor assembly is configured to produce a sensed load current output across the burden resistor over a predetermined range of magnitude that is proportionally related to the sensed motor load current over a predetermined range of full load current (FLC).

In an embodiment, the (RM) electronic overload relay includes a settable trip current generator that establishes a trip current threshold value that can range in value up to a predetermined reference voltage. The trip current value is proportionally related to a load current value that if exceeded, will indicate an overcurrent condition that is a predetermined percentage above the FLC specified for the motor. The (RM) electronic overload relay further includes a comparator configured to receive the settable trip current value from the trip signal generator and to receive the sensed current output of at least one of the one or more RM current sensor assemblies. The comparator is configured to compare the settable trip current value with the sensed current output of the at least one of the RM current sensor assemblies to produce an active state on an overload output when the received sensed current output is of a magnitude equal to or greater than the settable trip current value.

In another embodiment, each of the one or more current sensor assemblies is calibrated by sourcing a current into the current divider of the current sensor assembly that has a magnitude equal to the maximum FLC of the predetermined range. The resistance value of the burden resistor is adjusted until the sensed current output equals a maximum magnitude of its predetermined range.

In still another embodiment, each of the one or more current sensor assemblies is calibrated by sourcing a current into the current divider of the current sensor assembly that has a magnitude equal to the maximum FLC of the predetermined range plus a trip threshold percentage. The resistance value of the burden resistor is adjusted until the sensed current output equals a maximum magnitude of its predetermined range.

In yet another embodiment, the RM electronic overload relay further includes a comparator configured to receive the sensed current output of each RM current sensor assembly. The comparator is configured to compare the magnitudes of each of the received sensed current outputs and to generate an active state on a lost phase output when the difference between the sensed current output magnitudes is sufficient to indicate the loss of at least one phase.

In a further embodiment, the RM electronic overload relay includes an averager coupled to the sensed load current outputs for each of the RM current sensor assemblies. The averager is configured to produce an averaged sensed current output that is the average of the values of the sensed current outputs for each of the RM current sensor assemblies. The averaged sensed current output is proportional to the average of the load currents flowing in each of the branches of the motor branch circuit. The averaged sensed current output is coupled to an input of the comparator. The comparator is configured to receive the settable trip current value and the averaged sensed current output as inputs and produces an active overload output state when the averaged sensed current output is of a magnitude equal to or greater than the settable trip current value

In an embodiment, the predetermined reference voltage of the settable trip current generator is equal to the maximum magnitude of the predetermined sensed current output range.

In another embodiment, the low impedance conductor forming the main path, and the relatively higher impedance conductor forming the secondary path, are implemented as precision printed circuit board traces.

In a further embodiment, the relatively higher impedance conductor forming the secondary path is an insulated high impedance wire

In another embodiment, the core of the toroid transformer is embedded in the PC board, and the relatively higher impedance conductor forming the secondary path is made of precision printed circuit board trace is fed through the embedded core on an interconnect level below the surface of the printed circuit board.

In another aspect of the invention, a ratio metric (RM) electronic overload relay is configured to provide motor overcurrent protection for a motor in a three-phase AC motor branch circuit. Each branch of the motor branch circuit couples a different phase of a main AC power source to the motor through a circuit breaker and a motor starter. The motor starter includes a contactor of a predetermined size. The RM electronic overload relay provides the overcurrent protection over an entire range of possible full load current (FLC) values consistent with the contactor size. The RM electronic overload relay includes a ratio metric (RM) current sensor assembly configured to be coupled in series with each branch to sense motor load current flowing therethrough.

Each RM current sensor assembly includes a current divider configured to be conductively coupled in series with the branch, the current divider having a low impedance conductor forming a main path, a relatively higher impedance conductor forming a secondary path, and a current sensor magnetically coupled to the secondary path. The current sensor includes a core that is magnetically coupled to the higher impedance conductor as it is fed therethrough. A secondary surrounds the core and is coupled to a burden resistor. The RM current sensor assembly is calibrated to produce a sensed load current output signal that is proportionally related to the sensed motor load current over the range of (FLC).

The RM current sensor assembly also includes a settable trip current generator that establishes a trip current value that can range up to a predetermined reference voltage, the trip current value being proportionally related to a load current value that if exceeded, will indicate an overcurrent condition that is a predetermined percentage above the FLC specified for the motor. RM current sensor assembly further includes a comparator configured to receive the settable trip current value from the trip signal generator and to receive the sensed current output of at least one of the RM current sensors. The comparator is configured to compare the settable trip current value with the sensed current output of at least one of the RM current sensor assemblies to produce an overload output that is active when the received sensed current output is of a magnitude equal to or greater than the settable trip current value.

In an embodiment employing a passive voltage averager.

In a further embodiment, the variable trip current generator is a potentiometer that is coupled across the reference voltage.

### BRIEF DESCRIPTION OF THE DRAWINGS

FIG. 1 is a circuit diagram showing a thermal overload relay of the prior art employed in a motor starter of a branch motor circuit;

FIG. 2 is a circuit diagram showing an embodiment of an RM electronic overload relay of the invention, which has been substituted into the motor branch circuit of FIG. 1 for the prior art thermal overload protection relay;

FIG. 3 is a circuit diagram of an embodiment of an RM current sensor assembly of the invention that is employed by the RM electronic overload relay of the invention to sense the load current flowing in each branch (i.e. for each phase) of the motor branch circuit;

FIG. 4 is a view of an embodiment of the RM electronic overload relay of the invention implemented on a PC board with three RM current sensor assemblies of FIG. 3 incorporated therein; and

FIG. 5 is an external view of an embodiment of the electronic overload relay of the invention of FIG. 4, disposed within a protective housing.

### DETAILED DESCRIPTION

Embodiments of a ratio metric (RM) electronic overload relay (OLR) of the invention are disclosed that incorporate embodiments of an RM current sensor assembly of the invention. The RM electronic OLR of the invention is intended as a virtual drop-in replacement for prior art thermal overload relays as currently used in motor starters and other motor control circuits of branch motor circuits. Unlike thermal overload relays, the RM electronic OLR of the invention can be used for providing overcurrent protection for all motors having an FLC rating within the range of full load current (FLC) over which a contactor of a given frame size is operational. A trip current value generator can be controlled to establish a trip point threshold for any motor based on the FLC rating for the motor to be protected and a reference voltage. In accordance with NEC requirements, the trip current value must be above 1.05 times the FLC rating for the motor, and cannot exceed 1.15 times the FLC rating for the motor.

To monitor the load current in each branch of motor branch circuit, the RM electronic OLR employs an RM current sensor assembly of the invention. Each RM current sensor assembly produces a sensed current output signal in the form of a voltage that is proportional to the range of FLC values to be sensed. The only practical limit on this range is the contactor size with which the RM electronic OLR is paired in a motor starter. For example, a contactor having a frame size of 45 mm is typically spec'd to perform over a load current range of about 200 mA to 25 amps. A contactor having a frame size of about 55 mm is typically spec'd to handle up to 50 amps. The lower end of the range for the 55 mm frame size will typically overlap the range of the 45 mm frame size to some extent. The RM current sensor assembly can be size and cost optimized to produce the proportional output voltage signal inexpensively, while still maintaining the requisite accuracy for the application over variations in manufacturing the manufacturing process.

The RM current sensor assembly consists of two primary components: a current divider made up of low impedance main conductive path and an insulated higher impedance secondary conductive path coupled in parallel with a portion of the main path, and a current sensor magnetically coupled to the insulated secondary path. In a preferred embodiment, the current sensor is a toroid current transformer and the insulated high-impedance wire is electrically isolated from the core. The goal of the transformer is to produce a desired sensed current output voltage range e.g. 0-5 volts) that is: 1) produced as cost-effectively as possible; 2) proportional to the sensed current range within the requisite accuracy: and 3) capable of consistently reproducible performance in view of manufacturing tolerances.

The predominant factor in the cost of a current sensor is size. Thus, the current divider circuit can be used to divert just a fraction of the total load current to be sensed through the secondary path as a coarse approximation of the current range that the cost and size optimized transformer can effectively process. The component parameters of the transformer can then be used to refine the accuracy of the proportionality of the output signal, without ever requiring an accurately known current ratio of the current divider.

Thus, one approach to designing the RM current sensor assembly of the invention is to start with a cost optimized and highly manufacturable design for the toroid transformer, that will produce the desired output range from a range of input current that can be accurately and reliably processed by the cost-optimized current transformer. Then, one can set up the current divider to provide a coarse approximation of the amount of fractional current to be diverted from the branch to provide a range of input current that falls into the range that is appropriate to the size and component values of the transformer. This could be accomplished by, for example, establishing the conductors for the two paths based upon their DC resistances. Their DC resistances could be estimated by the geometries of the conductors and the resistivity of the material. This is easily done for PC board traces, and could also be done with a wire of known geometry and resistivity.

Those of skill in the art will appreciate that this coarse approximation is sufficient to bring the current range in the secondary path to a level that is compatible with the cost optimized transformer, but would not provide sufficient accuracy in the proportionality between the load current flowing in the branch and the sensed current output provided by the transformer. Thus, a pre-manufacture calibration is then performed to complete the tooling process. Prior art circuits that have incorporated a current divider to reduce the current to be sensed by a current sensor have always refined the actual ratio of impedances of the divider to know the precise current ratio between the paths to accomplish this calibration. However, the tooling calibration of the RM current sensor assembly performs a calibration that calibrates the entire currents sensor assembly (e.g. the main and secondary conductive paths, the transformer and the load resistor) rather than the current divider itself.

To calibrate the RM current sensor assembly of the invention, the maximum FLC of the range is sourced into the RM current sensor assembly, and the value of the burden resistor of the magnetically coupled current sensor can be adjusted until the sensed current output produces exactly the desired top value of the output signal (e.g. 5 volts). This accurately ties the top of the range of the sensed current output signal to the value of the FLC at the top of the range of FLC to be sensed, thus ensuring that the output signal of the RM current sensor assembly is accurately proportional to the sensed current flowing in the branch over the entire range of FLC. This also calibrates the entire current sensor assembly, even though the precise values of the impedance of the current divider are not relevant or known. Moreover, this calibration can also be performed to incorporate the 10% threshold window (between 1.05 and 1.15) by simply calibrating the top value of the output range to be produced by the top value in the range of FLC times 1.10.

Increased accuracy can be achieved if desired, by laser trimming the burden resistor. However, manufacture of the the RM electronic OLR is simplified by merely repeatably manufacturing the main and secondary path conductors as estimated, rather than having to manufacture them as calibrated to some exacting value of AC impedance. In accordance with the invention, only a single parameter in the form of the burden resistor of the current transformer needs to be adjusted in the calibration process.

By leveraging the ratio metric effect of the current divider, the RM current sensor assembly can be optimized for size and cost, enabling the sensed current to be generated over a signal range of, for example, 0 to 5 volts. This permits implementation of the RM electronic OLR using precision printed circuit board techniques along with size and cost optimized circuit components. This makes the RM electronic OLR cost competitive with thermal overload relays of the prior art while offering numerous additional advantages. The only required adaptation in substituting the RM electronic OLR for a thermal overload relay of the prior art is that a power supply is required to operate the circuit components of the electronic relay of the invention. This power can be derived from the main power, or it can be provided using a dedicated supply or long-life battery for example.

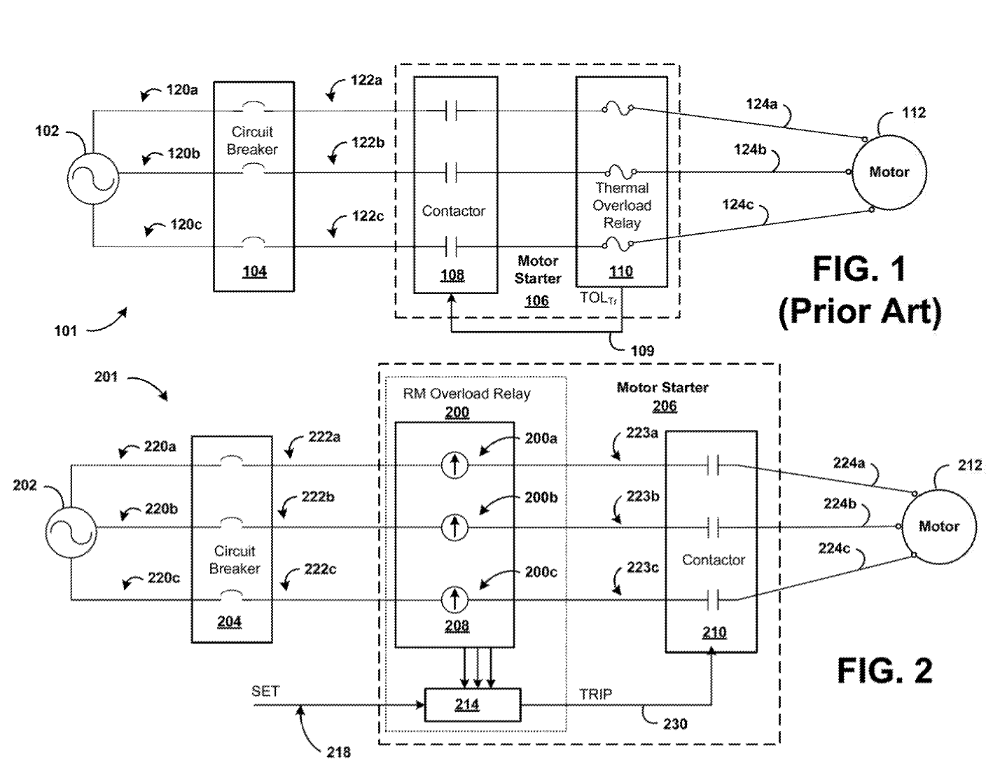

FIG. 1 illustrates a branch motor circuit 101 of the prior art that includes a motor 112 and a main three-phase AC power source 102, each phase coupled to the motor 112 through one of three circuit branches a, b, and c. The main power source 102 is coupled through branch circuit conductors 120a-c to circuit breaker 104. The circuit breaker 104 couples and decouples the three phases of the main power source 102 to the motor starter 106 through branch conductors 122a-c respectively. The motor starter 106 is then coupled to motor 112 through branch circuit conductors 124a-c. Before start-up, the circuit breaker 104 is closed so that main power 102 is provided to motor starter 106. This provides power to the magnetic coil of the contactor 110 so that when a motor start-up is initiated, the contactor 110 can be closed to couple motor 112 to the three phases of main power source 102 through branch conductors 124 a-c.

The motor starter 106 also includes a requisite thermal overload relay 110, which is designed to correlate with the maximum full load current (FLC) of the motor drawn from each phase of main power source 102 so that it trips at or near a predetermined threshold of load current flowing in the branches for each phase. That threshold must be above 1.05 times the maximum rated full load current (FLC) of motor 112, but no higher than 1.15 times the maximum rated FLC of motor 112 (as per the industry requirements discussed above). As long as the current remains below the established trip current threshold or trip point, the contactor 108 continues to operate normally with its contacts closed to provide the three phases of main power 102 to motor 122. During operation, should the load current drawn by the motor 112 through any of the phases exceed the trip point long enough for the heated bimetal elements of the thermal overload relay 110 to trip and open its contacts, thermal overload relay 110 will provide an interrupt signal to deny power to the coil of contactor 108. This control signal is represented by thermal overload trip signal TOL_{Tr} 109. Interrupting power to the contactor coil causes the contactor 108 to open and decouple the motor 112 and its associated branch conductors from all three phases of main power 102.

As previously discussed above, the physical components of the thermal OLR 110 must be sized and designed to establish a trip point at a threshold magnitude of load current that is greater by a predetermined percentage than the maximum full load current specified for a given motor design. Based on the NEC requirement that an overload must not trip below 1.05 times the FLC and must trip below 1.15 times the FLC of the motor, the threshold can be set at 1.10 times FLC, which is halfway between 1.05 and 1.15 times FLC. The range over which the trip point can be adjusted for a given variant of a thermal OLR 110 is quite narrow (e.g. about 1.2 to 1.8 amps). If one assumes an average range of 1.6 amps per variant, and an overlap of a few tenths of an amp for each range, it might require 18 to 20 variants of a thermal OLR 110 to cover the range of FLC that is compatible with a contactor of a given frame size. For example, the range of FLC typically associated with a contactor of 45 mm is a few milliamps up to 25 amps. This requires that all of these variants be manufactured and inventoried to cover this range. In addition, should motor 112 have to be replaced with a motor that draws a full load current (FLC) that falls outside of the range over which the tripping point of the currently installed OLR 110 can be adjusted, the thermal OLR 110 would have to be replaced with a variant of that device that is designed to operate with the FLC of the new motor. As previously discussed, the replacement process is not an insignificant inconvenience.

Those of skill in the art will appreciate that the range of FLC of up to 25 amps is associated with one commonly employed frame size of contactor of 45 mm. However, the current range might be expanded to, for example 50 amps should a contactor be employed having a frame size up that is typically 55 mm. In this case, a different family of variants (perhaps as many as 5 to 10 additional variants) of a thermal overload relay would have to be manufactured and inventoried to accommodate the larger contactor. The larger contactor requires a different housing for the thermal OLR 110, and contact size and contact separation must be expanded to ensure that the contacts of the thermal relay are aligned with, and are of roughly the same size as, those of the larger frame size of the contactor.

FIG. 2 illustrates a branch motor circuit 201 into which the thermal overload relay 110 from FIG. 1 has been replaced with the Ratio Metric (RM) Electronic Overload Relay (OLR) 200 of the invention. Branch motor circuit 201 includes a motor 212, a main three-phase AC power source 202, each of the three phases being coupled to the motor 212 through one of three circuit branches a, b, and c. The main power source 202 is coupled through conductors 220a-c to circuit breaker 204. The circuit breaker 204 couples and decouples the motor starter 206 to and from the main power source 102 through branch circuit conductors 222a-c. The motor starter 206 is then coupled to motor 212 through branch circuit conductors 224a-c. Before start-up, the circuit breaker 204 is closed so that the three phases of main power 202 is provided to motor starter 206. This provides power to the magnetic coil of the contactor 210 so that when motor start-up is initiated, the contacts of contactor 210 are closed, and the motor 212 is coupled to the main power source 202 through branch conductors 124 a, b, c.

The RM Electronic OLR 200 of the invention in FIG. 2 has been flipped in the physical order in which it appears with respect to the contactor 210 in motor starter 206. Those of skill in the art will appreciate that unlike the thermal OLR 110, the RM Electronic OLR 200 requires a power source to initially sense current flow and this change in the ordering is merely intended to reflect that power requirement. Those of skill in the art will appreciate that the power required to operate the RM electronic OLR 200 of the invention may be derived from main power source 202, or it could be independently sourced through a dedicated power source such as a long life battery. RM electronic OLR 200, like the thermal OLR 110, also meets the NEC requirement that it provide a trip current value that is above 1.05 times the maximum FLC of motor 212 but not above 1.15 times the maximum rated FLC of motor 212.

Rather than correlating a thermal response to that threshold level of load current and reacting to the temperature of heated bimetal strips as a function of load current as does the thermal OLR 110, the RM electronic OLR 200 of the invention employs an RM current sensor assembly of the invention 200a-c (one for each phase) to generate a sensed current output signal that is proportional to the load current flowing in each phase. An embodiment of the RM current sensor assembly 200a-c employs a current divider and a magnetically coupled sensor. The current divider is used to feed the current sensor with only a fraction of the total load current flowing in the circuit branch for each phase. Because the size of a current sensor must increase to accommodate an increase in the magnitude of the current it is expected to sense, reducing the current actually sensed to a fraction of the total load current permits the current sensor to be optimized for size and cost, regardless of the magnitude of the maximum value of the range of FLC.

This also makes it possible to establish the range of the sensed current output signal to be one that is easily processed at digital levels by components on a printed circuit board (e.g. 0 to 5 volts). The sensed current output range is calibrated during tooling to be directly proportional to the full range of FLC current for a given contactor frame size, and thus requires no variants to cover the full range as is required by thermal overload devices of the prior art. Put another way, the trip point for the RM electronic OLR 200 can be adjusted to provide overload protection for any motor 212 having an FLC falling within the range of FLC associated with the frame size of contactor 210.

In an embodiment, the three sensed current outputs for each the three phases can be averaged by processing logic 214 to produce an averaged sensed current output of the three phases, and this value is compared to a threshold trip value established based on the FLC rating of the motor 212 being protected. The trip current threshold value can be set through a user input SET 218 that selects the value based on a reference voltage representing the highest possible trip current value. An analog or digital potentiometer is one way to provide this selectable trip value. As long as the averaged sensed current value stays below the threshold current value selected as the trip point, the coil of contactor 210 is permitted to maintain the contacts in a closed state to couple main power 202 to motor 212. If the averaged sensed current output value representing the average load current flowing in the three phases exceeds the selected trip current threshold magnitude, the RM electronic OLR 200 generates a signal EOL_{Tr} 216 that denies power to the coil of the contactor 210. This opens the contacts of the contactor 210 and the motor 212 becomes isolated from main power source 202.

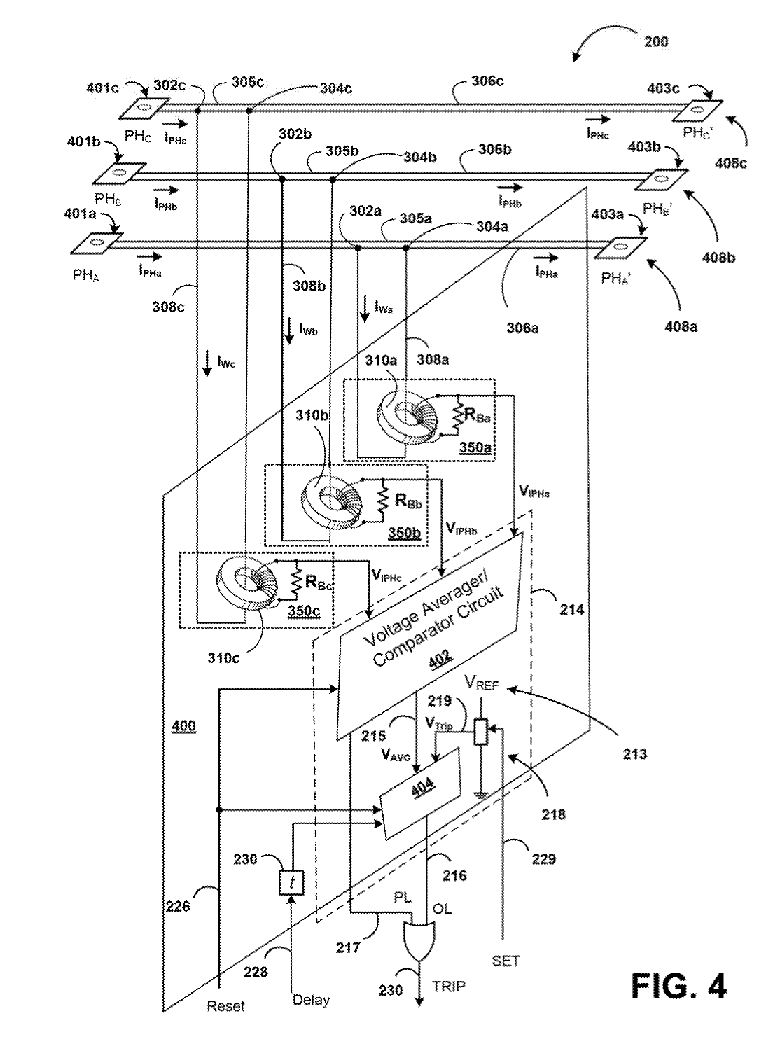

Thermal OLR 110 has an inherent thermal delay that subverts nuisance tripping or tripping on the motor inrush currents before the motor is fully up to speed. The RM electronic OLR 200 has no such inherent delay. Therefore, a delay t 230, FIG. 4 is introduced upon motor start-up by processing logic block 214 to initially suppress detection and thereby prevent nuisance tripping and tripping on inrush load currents. This time delay can be adjusted through a control input (DELAY 228, FIG. 4) but is typically on the order of about 6 seconds for most applications. Those of skill in the art will appreciate that the delay can be extended for high inertia loads that require longer starting times. This delay can also be used to avoid tripping on very short duration excursions over the threshold value as well, by requiring that the sensed current output value remain at or above the threshold trip current value for a time t before permitting a comparator (404, FIG. 4) in the logic block 214 to latch.

Those of skill in the art will appreciate that although the most common motor branch circuits will typically have three branches corresponding to three phases of AC power, branch circuits have been implemented with other numbers of branches. For example, many small electric motors operate on only one or two phases, and some (e.g. electric motors for controlling various functions on jet airplanes) have used as many as six phases. Thus, embodiments of the RM electronic OLR 200 of the invention can be scaled up or down to operate for any number of phases supplied through the same number of branches. To scale up or down, one need only increase or decrease the number of RM current sensor assemblies 200a-c to match the number of branches of the motor branch circuit.

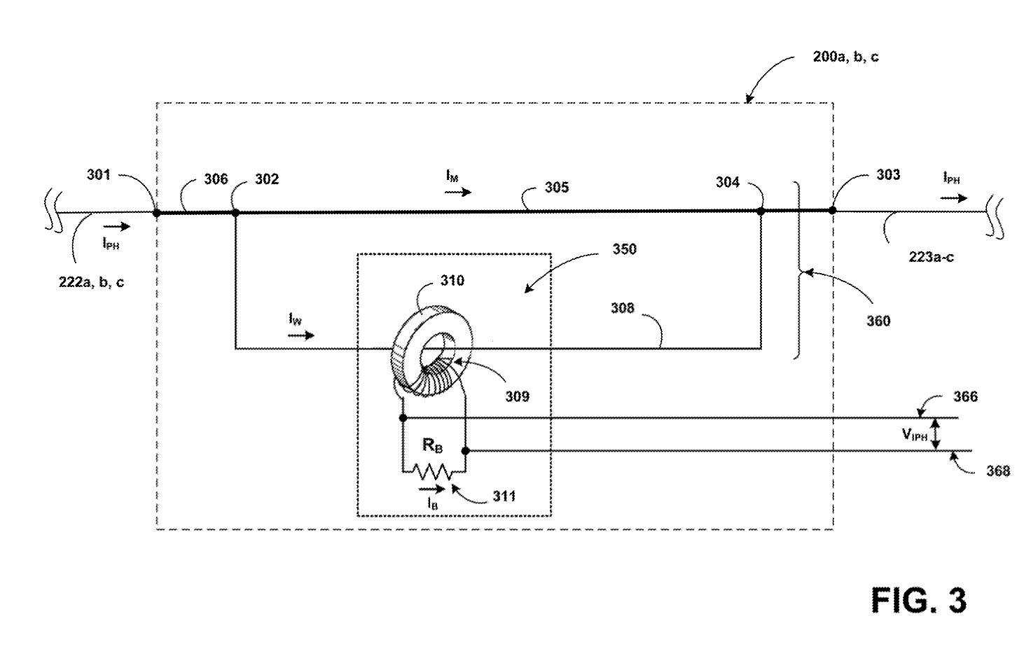

FIG. 3 illustrates an embodiment of the RM current sensor assemblies 200a, b, c of FIG. 2 in more detail. The RM current sensor assembly 200a-c includes two primary subcomponents: current divider 360 and magnetic current sensor 350. Current divider 360 includes low-impedance conductor 306 and relatively higher impedance conductor 308, which is coupled in parallel to the low impedance conductor 306 at circuit junctions 302 and 304. This establishes a current divider between junctions 302 and 304 respectively, the current divider having a main path 305 formed between circuit junctions 302 and 304 by low impedance conductor 306, and a secondary path formed by higher impedance conductor 308 between between junctions 302 and 304.

In an embodiment, current sensor 350 is a toroid current transformer that is magnetically coupled to the secondary path 308 of the current divider by feeding the higher impedance conductor 308 through the core 310 of the transformer so that it senses only the fractional current diverted at circuit junction 302 from the current flowing in the low impedance conductor 306. Because the diverted current I_{W} flowing in the secondary path formed by higher impedance conductor 308 is only a small fraction of the load current I_{PH} that is flowing into the transformer 350, the core 310 of the transformer can be very small and the toroid transformer 350 can be very inexpensive. The higher the impedance of conductor 308, the smaller the range of fractional current that is to be sensed by the magnetically coupled sensor 350. Conductor 308 can be, for example a higher impedance wire, or it could be implemented using a precision printed circuit board trace that may include a resistor in series therewith.

A burden resistor R_{B} 311 is coupled between the leads of the secondary formed by the windings 309 around the core 310 and produces a sensed current output voltage signal V_{IPH} 366, 368 that is proportionally related to the fraction of the load current that is flowing in the secondary path, and that proportionality will be dictated by parameters of the current sensor design, such as the size and material composition of the core 310, the number of turns 309, and the value of the burden resistor R_{B} 311. The proportionality between the sensed current output voltage across R_{B} 311 and the load current flowing into the circuit node 302 is also a function of the current ratio of the current divider 360.

When tooling a particular design of the RM current sensor 200a-c of the invention for mass manufacture, one can start with a desired output voltage range for the sensed current output V_{IPH} 366, 368 that will represent the range of load current to be sensed over the range of FLC. One can then optimize the current sensor 350 to minimize size and cost, and this will define the input range of current flowing in the secondary path formed by higher impedance conductor 308 that the sensor 350 will transform in to the desired output range. The current ratio can be roughly estimated based on an estimation of the impedance ratio of the two paths based on, for example the DC resistance of the conductors 306, 308. This approximation can be measured, or simply inferred from the geometric proportions of the conductors 306, 308 as well as the resistivity of the material from which they are made. This rough approximation can be used to estimate the range of diverted load current I_{W} that will flow in the secondary path 308 so that it falls within the range range of current that is suitable for the optimized current sensor 350.

Prior art implementations of current sensors using a current divider always calibrate the current divider to have a predetermined current ratio by forcing a known current and then using some type of trimming process to establish the predetermined ratio of the current divider to a desired degree of accuracy. Performing such a calibration on the current divider only calibrates the ratio of the current divider, not the entirety of the current sensor assembly 200a-c. For the present invention, the current divider is simply used only to divert a small enough fraction of the load current to enable size and cost optimization of the magnetically coupled current sensor, and to have an accuracy that is sufficient to provide a first approximation of the fractional current so that it is in the range of input current appropriate for the current sensor. The current sensor assembly of the invention is then calibrated as a whole, by sourcing a known current that is equal to the maximum value in the range of FLC to be sensed and the value of the burden resistor R_{B} 311 is adjusted until the highest value of the sensed current output range is produced. Thus, the proportionality of the current divider as well as the current sensor is calibrated together, and the precise ratio of the current divider does not have to be known or calibrated to a known value with any precision.

In an example, one could optimize for size and cost a current sensor that would operate properly based on approximately 500 mA of maximum current flow through the secondary path 308 for a load current magnitude at the top of the desired FLC range. Thus, if the FLC range is a few hundred milliamps to 25 amps, then approximately 500 mA would represent the maximum FLC value of 25 Amps. If the secondary of the toroid is given 10 turns (a 10:1) ratio, it would produce an output current in the secondary of approximately 50 mA for 25 amps. If burden resistor R_{B} 311 is initially chosen to be 100 Ohms, the DC signal voltage across burden resistor R_{B} 311 would have a signal of about 5 volts at 25 amps.

Conductors 306 and 308 can be manufactured to have known DC impedances based on resistivity and geometry of the conductors. This can be used as a first pass approximation for the design by which to ensure that the fraction of the current is going to yield the desired approximately 500 mA of current for 25 Amps flowing into circuit node 302. Thus, in an embodiment, the approach to optimizing the components of RM current sensor assembly 200a-c of the invention for a given current range (regardless of what the maximum current is for the range), would be to first choose a DC resistance of the secondary path conductor 308 to achieve an approximate DC current ratio of 50:1.

A single pre-manufacture calibration can then be performed for the design by which to tool the device for mass manufacture. This is accomplished by sourcing the amount of current that represents the top of the range (e.g. 25 amps AC) and adjusting the burden resistor R_{B} 311 to produce the maximum 5 volt output for sensed current output of the current sensor. Once calibration establishes the value of the burden resistor R_{B} 311 to achieve the 5 volt output at the maximum FLC of the range for a given size, length and resistivity for the conductors 306, 308, and for a given core 310 size and number of windings 309 for the toroid transformer 350, the RM current sensor assembly 200a-c can be manufactured using those same physical parameters of the components established during calibration for each RM current sensor assembly 200a-c of the invention. So long as the manufacturing tolerances meet the required accuracy of the application (about 10%), no further calibration is required. Those of skill in the art will appreciate that further accuracy can be achieved by, for example, laser trimming the burden resistor during manufacture to a tighter tolerance if desired.

This method of calibration of the invention eliminates the need to precisely establish the ratio of AC impedances of the paths for the current divider, and it ensures that the current sensor is also part of the calibration as well. Moreover, as will be discussed later, the tripping threshold of 10% can be calibrated into the range of values by simply using a calibration current for the top of the range that is equal to the top value of the range of FLC plus the 10% threshold value. Thus, one can simply force the 5V maximum sensed current output value in he example above, but to be generated when forcing a current 27.5 amps into the current sensor assembly design rather than 25 amps as provided in the example.

Those of skill in the art will recognize that if a wire is used as the conductor 308 for the higher impedance secondary path, there will be a tradeoff between the impedance of a wire and the robustness of that wire. Those of skill in the art will also appreciate that if conductor 308 is a printed circuit board trace, it can be routed at an interconnect level below the surface of the board such that it can be made to pass through the middle of a partially embedded core 310. This makes the issue of robustness less of a concern. For a PC board embedded toroid, the windings 309 can also be implemented as wire “stitches” looped over the partially embedded core 310. Those of skill in the art will recognize that other magnetically coupled current sensors could also be substituted for toroid transformer 350. For example, a Hall Effect device or a Rogowski coil could also be used in lieu of the toroid transformer of the preferred embodiment. Those of skill in the art will recognize, however, that these alternative embodiments of magnetically coupled sensors may present issues that could limit their applicability in the present application.

The RM current sensor assemblies 200a-c are coupled between branch conductors 222a-c and branch conductors 223a-c (FIG. 2) at input circuit contacts 301 and 303 through low impedance conductor 306 respectively. Low impedance conductor 306 can be, for example, a bus bar, a PC board trace, or the like. Thus, the motor load currents I_{PHa}, I_{PHb}, and I_{PHc} (generically shown as I_{PH}) flowing through each of these branch conductors for each of the phases are sensed only from the diverted fraction of the total motor load current flowing in the secondary path formed by conductor 308.

FIG. 4 illustrates one embodiment 200 of the Ratio Metric (RM) Electronic Overload Relay (OLR) 200 of the invention, as it could be implemented using a printed circuit board 400. Bus bars 408a, b and c are made up of low impedance conductors 306a-c respectively, and contacts 401a-c corresponding to circuit junctions (301a-c, FIG. 3) and contacts 403a-c corresponding to circuit junctions (303a-c, FIG. 3). RM current sensor assemblies 200a-c are shown with higher impedance conductors fed through core 310a-c and coupled to circuit junctions 302a-c and 304a-c on low impedance conductors 306a-c. As discussed previously, the bus bars 408a-c could be printed circuit board traces, as is true of the higher impedance conductors 308a-c.

In an embodiment, the sensed current output voltages V_{IPHa}, V_{IPHb} and V_{IPHc} from the RM current sensors assemblies 200a-c are all outputs that represent a value that is proportionally related to the sensed motor load current flowing in the branch for each phase of AC power source 202, FIG. 2. In an embodiment, they can be averaged by voltage averager/comparator block 402. Block 402 includes a circuit for averaging the three voltages, such as a passive voltage averager, to produce a single averaged sensed current output V_{avg} 215. Those of skill in the art will recognize that it is not absolutely necessary to average the sensed current outputs for all of the phases of the motor branch circuit, as they are going to be very similar to one another; only one such output can be used if the reduction in accuracy is acceptable. Put another way, if a small difference between the phase currents can be tolerated, one of the sensed current outputs may be used as the input to the comparator 404 as discussed below.

V_{avg} 215 (or one of the sensed current outputs) is then compared to a trip current value V_{Trip} 219 by comparator 404. Those of skill in the art will recognize that the trip current value V_{Trip} 219 is generated by a settable trip current generator (e.g. an analog or digital potentiometer) from reference voltage V_{REF} 213 under control of input SET 229. In an embodiment, the value of V_{REF} 213 is equal to the maximum sensed current output value for the range of FLC, such as 5 volts. In an embodiment, the calibration of the RM current sensor assemblies 200a-c has been performed to incorporate the 10% threshold required for the trip current within the range of the sensed current outputs V_{IPH a}, V_{IPHb} and V_{IPHc} such that 5 volts will be equated to 27.5 amps for an FLC range up to 25 amps. In another embodiment, V_{REF} 213 can incorporate the 10% threshold value, and would be equal to 5.5 volts. Either way, the trip current level that is established from V_{REF} 213 is 10% above the FLC for the motor 212, and it provides the trip signal level that is compared to the sensed current output(s) generated by the RM current sensor assemblies based on the load current flowing in the branches. Based on the requirements for overcurrent tripping specified by the NEC, the threshold percentage of 10% above the FLC of 25 amps is chosen because it is halfway between the no trip level of 1.05 and the maximum trip level of 1.15 specified by the NEC.

Those of skill in the art will recognize that there are a number of ways to derive a threshold trip value from a reference voltage. One way is to use an analog potentiometer 218 across V_{REF} 213 to generate an output voltage that varies from 0 to V_{REF} 213 using a control signal (e.g. SET input 229). Potentiometer 218 is used to offset V_{REF} 213 to establish the trip point value V_{Trip} 219 between zero and V_{REF} 213. Those of skill in the art will appreciate that a digital potentiometer can also be used. An example of one is the Digital Pot MCP4017/18/19 made by Microchip. Other techniques of sweeping a reference voltage using a control input can also be used. Input signal SET 229 can be used by a user to control the potentiometer 218 to set the trip current value across the entire range of expected motor FLC from just above 0 volts to V_{REF}. This eliminates the need to manufacture and inventory many variants of an overload relay for given range of FLC as previously discussed.

Thus, for a range of a few hundred milliamps to 25 amps associated with a contactor frame size of 45 mm (those of skill in the art will appreciate that the smallest electric motors actually operate at a minimum of about 100 to 200 milliamps and not zero), the device can be calibrated pre-manufacture as described above. The burden resistor can be adjusted to a value that outputs V_{IPHa-c}=5 volts when a 27.5 amp input current is induced or sourced at the inputs of the RM current sensor assemblies 200a-c. This has the effect of building the 10% threshold into the calibrated range such that V_{REF} 213 can be set at 5 volts.

For example, if a user wishes to use a 25 amp motor, the user can input 25 amps FLC through input SET 229 and SET 229 will adjust the potentiometer to establish the trip value of V_{Trip} 219=V_{REF} 213=5 volts, which represents the trip current value of 27.5 amps for a 25 amp FLC motor. This also means that the user can simply enter in the FLC value spec'd for the motor being used (up to the maximum value of the FLC and the 10% trip threshold will always be reflected in the trip value V_{Trip} 219 established through the SET 229 input. For example, a user can enter a value of 15 amps through SET 229 input when using a 15 amp FLC motor, and the generated trip current value of V_{Trip} 219=3 volts will be delivered by the pot to the comparator, this value of V_{Trip} 219 will represent a 16.5 amp overcurrent trip current threshold or trip point.

In an embodiment, the average sensed current output value V_{avg} 215 of the sensed current outputs V_{IPHa}, V_{IPHb} and V_{IPHc} from the three RM current sensor assemblies 200a-c is compared to the value of VTrip 219 using a comparator 404. Comparator 404 will preferably latch a change to an active state of its output when V_{avg} 215 equals or slightly exceeds the value of V_{Trip} 219. This change to an active state will reflect a change in the state of overload signal OL 216, indicating that an overcurrent condition has been detected. As previously discussed, the delay t 250 can be used to prevent nuisance tripping at right around the threshold by requiring that the averaged sensed current output remain above the threshold value set by the SET input for a time t before latching a change of state indicating an overload. The length of the delay t 250 can be selected using control input Delay 228.

In an embodiment, block 402 also includes a comparator that compares each of the values of all three sensed current outputs V_{IPHa}, V_{IPHb} and V_{IPHc} to one another to detect a difference between the three values that indicates a loss of one or more phases of the motor circuit. Those of skill in the art will appreciate that phase loss can occur because of a lightning strike that affects main power source 202, it could be due to a faulty or disconnected conductor in a branch supplying one of the phases, one of the contactor contacts is faulty, or possibly problem with the motor 212 itself. If such a loss of phase is detected, a change to an active state of the output PL 217 is generated. OL 216 and PL 217 are logically OR'd together to produce a single TRIP signal 230 that changes to an active state in the presence of either an overcurrent or “loss of phase” condition. It is TRIP signal 230 that deprives the power to the coil of the contactor 210 when it is in an active state.

Should the RM electronic OLR 200 of the invention be tripped for either an overcurrent condition or a loss of phase, signal TRIP 230 can be used to deny power to the coil of contactor 210, FIG. 2. This causes the contactor's contacts to open and this decouples motor 212, FIG. 2 from main power 202, FIG. 2. The RM electronic OLR 200 can be reset after a TRIP condition is detected, either automatically based on a motor restart signal being reissued, or it can be manually reset. Signal Reset 226 can be used to reset the comparator 404 and the comparator in 402 to unlatch the OL 216 overload signal and/or the phase loss PL 217 signal respectively. The reset will then deactivate the TRIP 230 output that denies power to the coil of the contactor 210, thus allowing the contactor 210 to re-close its contacts on an ensuing restart of motor 212, FIG. 2. Input signal Delay 228 can be used to adjust the duration of the start-up delay of the RM electronic OLR 200 to avoid nuisance tripping or tripping on motor inrush currents during motor start-up.

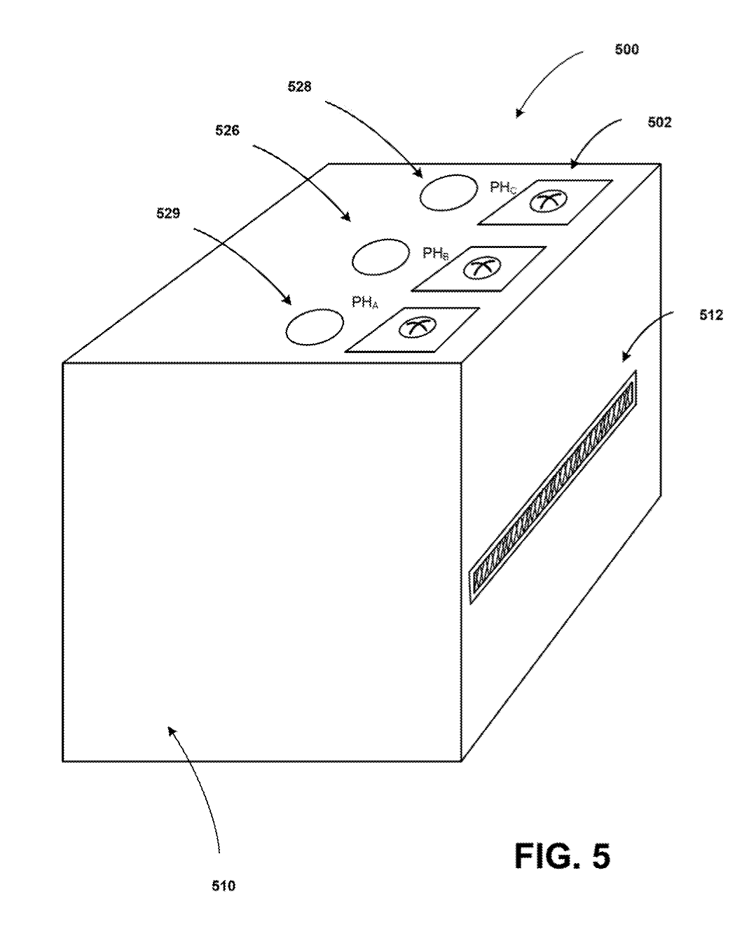

FIG. 5 illustrates an embodiment 500 of the RM electronic OLR 200 disposed within a housing 510. Such housings are well-known in the art and can be manufactured in various known configurations from known materials. Contacts 502 are provided for coupling one end of the bus bars to the conductors of the branch circuit for each phase. Another set of contacts (not shown) would be similarly established to couple the opposite end of the bus bars 408a-c. These contacts could be the same or similar to contacts 502, or they could be established in a different location in the housing. Opening 512 can receive an edge connector of PC board 400, FIG. 4 and permit coupling to, for example a ribbon connector that enables coupling of I/O signals such as OL 216, SET 229, DELAY 228 and RESET 226 to motor control circuitry well-known in the art. Button 528 can permit manual selection of delay duration on start up through actuation of the DELAY input 228, button 526 can provide a manual operation of the RESET 226 input to reset the RM OLM 200. Button 529 can be used to manually set the trip point value through the SET input signal 229. These inputs can also be software controlled by the motor control circuitry through the ribbon connector to the PC board of RM electronic OLR 200.

Those of skill in the art will appreciate that the RM electronic OLR 200 of the invention will operate in the same manner over the entirety of any range of FLC for which it is designed and calibrated. The upper FLC value of the range is determined by the frame size of the contactor. The frame size increases as the magnitude of load current that the contactor must handle increases, because the size of the contacts and the coil, and therefore the housing of the contactor, must increase commensurately. Thus, like prior art overload relays, the physical size of the RM electronic OLR 200 must also increase to maintain alignment with the contacts of the contactor as the frame increases. The range of a few hundred milliamps to 25 amps is a range that is typically associated with a contactor frame size of 45 mm. A 55 mm contactor is typically used to increase the range to 50 amps. Thus, while there will be variants of the RM electronic OLR 200 of the invention with respect to sizing to match contactors of standard sizes, unlike prior art overload relays, there will be no need for variants to operate over the entire range of FLC associated with each standard fame sizes.

The RM electronic OLR of the invention can be scaled up or down to operate for any number of phases (and therefore branches) of a motor branch circuit. Many small electric motors operate on only one or two phases, and some (e.g. electric motors for controlling various functions on jet airplanes) have used as many as six phases. To scale up or down, one need only increase or decrease the number of RM current sensor assemblies to match one for each phase.

It should be pointed out that accept for delays during which overcurrent detection is suppressed, the RM current sensor assemblies of the RM electronic OLR are continuously sensing load current and continuously comparing the sensed magnitude of the load current (whether for a single branch or one that is averaged over all branches) to the settable trip point to detect an overload should one occur.

Finally, those of skill in the art will recognize that there may be several ways in which the various processing and control functions described herein can be implemented. For example, there may be other known techniques by which the sensed output signals may be averaged. Indeed, they may not have to be averaged at all, given that typically there is little difference between the load currents drawn for each phase. Thus, for certain applications one could merely use one phase output for comparison to the trip value. In addition, there may be other ways to provide a reference voltage or to derive a threshold trip value therefrom. There are many techniques for implementing comparators and for generating programmable delays. Such variations are all deemed to be within the scope of the invention.

What is claimed is:

1. A ratio metric (RM) electronic overload relay for providing motor overcurrent protection for a motor in a motor branch circuit, the RM electronic overload relay comprising:
one or more ratio metric (RM) current sensor assemblies, each configured to be coupled in series with one of one or more branches of the motor branch circuit to sense motor load current flowing therethrough, each of the one or more RM sensor assemblies including:
a current divider including:
a low impedance conductor configured to be conductively coupled in series with the branch; and
a higher impedance conductor coupled to two points along the low impedance conductor,
wherein the low impedance conductor forms a main path of the current divider between the two points and the higher impedance conductor forms a secondary path of the current divider; and
a current sensor magnetically coupled to the secondary path, the current sensor including:
a core through which the higher impedance conductor is fed as a primary;
a secondary of one or more windings about the core; and
a burden resistor that is coupled to the secondary,
wherein the RM current sensor assembly is configured to produce a sensed load current output, across the burden resistor, over a predetermined range of magnitude that is proportionally related to the sensed motor load current over a predetermined range of full load current (FLC); and
a settable trip current generator that establishes a trip current threshold value that can range in value up to a predetermined reference voltage, the trip current value being proportionally related to a load current value that if exceeded, will indicate an overcurrent condition that is a predetermined percentage above the FLC specified for the motor; and
a comparator configured to receive the settable trip current value from the trip signal generator and to receive the sensed current output of at least one of the one or more RM current sensor assemblies, the comparator configured to compare the settable trip current value with the sensed current output of the at least one of the RM current sensor assemblies to produce an active state on an overload output when the received sensed current output is of a magnitude equal to or greater than the settable trip current value.

2. The RM electronic overload relay of claim 1, wherein each of the one or more current sensor assemblies is calibrated by sourcing a current into the current divider of the current sensor assembly having a magnitude that is equal to the maximum FLC of the predetermined range, and adjusting a resistance value of the burden resistor until the sensed current output equals a maximum magnitude of its predetermined range.

3. The RM electronic overload relay of claim 1, wherein each of the one or more current sensor assemblies is calibrated by sourcing a current into the current divider of the current sensor assembly having a magnitude that is equal to the maximum FLC of the predetermined range plus a trip threshold percentage, and adjusting a resistance value of the burden resistor until the sensed current output equals a maximum magnitude of its predetermined range.

4. The RM electronic overload relay of claim 1, further comprising a comparator configured to receive the sensed current output of each RM current sensor assembly, the comparator configured to compare magnitudes of each of the received sensed current outputs and to generate an active state on a lost phase output when the difference between the sensed current output magnitudes is sufficient to indicate the loss of at least one phase.

5. The RM electronic overload relay of claim 1, further comprising:
an averager coupled to the sensed load current outputs for each of the RM current sensor assemblies, the averager configured to produce an averaged sensed current output that is the average of the values of the sensed current outputs for each of the RM current sensor assemblies, the averaged sensed current output being proportional to the average of the load currents flowing in each of the branches of the motor branch circuit, the averaged sensed current output being coupled to an input of the comparator,
wherein the comparator is configured to receive as inputs the settable trip current value and the averaged sensed current output and to produce an active overload output state when the averaged sensed current output is of a magnitude equal to or greater than the settable trip current value.

6. The RM electronic overload relay of claim 3, wherein the predetermined reference voltage of the settable trip current generator is equal to the maximum magnitude of the predetermined sensed current output range.

7. The RM electronic overload relay of claim 1, wherein the low impedance conductor forming the main path, and the relatively higher impedance conductor forming the secondary path are made of precision printed circuit board traces.

8. The RM electronic overload relay of claim 1, wherein the relatively higher impedance conductor forming the secondary path is an insulated high impedance wire.

9. The RM electronic overload relay of claim 7, wherein the core of the toroid transformer is embedded in the PC board, and the relatively higher impedance conductor forming the secondary path is made of precision printed circuit board trace is fed through the embedded core on an interconnect level below the surface of the printed circuit board.

11. A ratio metric (RM) electronic overload relay configured to provide motor overcurrent protection for a motor in a three-phase AC motor branch circuit, each branch of the motor branch circuit coupling a different phase of a main AC power source to the motor through a circuit breaker and a motor starter, the motor starter having a contactor of a predetermined size, said electronic overload relay operative to provide the overcurrent protection over an entire range of possible full load current (FLC) values consistent with the contactor size, the electronic overload relay comprising:
three ratio metric (RM) current sensor assemblies, each configured to be coupled in series with one of the three branches to sense motor load current flowing therethrough, each RM current sensor assembly including:
a current divider configured to be conductively coupled in series with the branch, the current divider having a low impedance conductor forming a main path, and a relatively higher impedance conductor forming a secondary path; and
a current sensor magnetically coupled to the secondary path, the current sensor including:
a core that is magnetically coupled to the higher impedance conductor that is fed therethrough;
a secondary that includes one or more windings surrounding the core; and
a burden resistor that is coupled across the secondary,
wherein the RM current sensor assembly is calibrated to produce a sensed load current output signal that is proportionally related to the sensed motor load current over the range of (FLC) in its entirety; and
a settable trip current generator that establishes a trip current value that can range in value up to a predetermined reference voltage, the trip current value being proportionally related to a load current value that if exceeded, will indicate an overcurrent condition that is a predetermined percentage above the FLC specified for the motor; and
a comparator configured to receive the settable trip current value from the trip signal generator and to receive the sensed current output of at least one of the RM current sensors, the comparator configured to compare the settable trip current value with the sensed current output of at least one of the RM current sensor assemblies to produce an overload output that is active when the received sensed current output is of a magnitude equal to or greater than the settable trip current value.

12. The RM electronic overload relay of claim 11, further comprising a comparator configured to receive each of the sensed current outputs of the RM current sensor assemblies, the comparator configured to compare the values of the received sensed current outputs and to generate a lost phase output that is active when the difference between the sensed current output values is sufficient to indicate the loss of at least one of the phases.

13. The RM electronic overload relay of claim 11, further comprising:
an averager coupled to the sensed load current outputs for each of the RM current sensor assemblies, the averager configured to produce an averaged sensed current output that is the average of the values of the sensed current outputs for each of the RM current sensor assemblies, the averaged sensed current output being proportional to the average of the load currents flowing in each of the branches, the averaged sensed current output being coupled to an input of the comparator,
wherein the comparator is configured to receive the settable trip current value and the averaged sensed current output and to produce an overload output that is in an active state when the averaged sensed current output is of a magnitude equal to or greater than the settable trip current value.

14. The RM electronic overload relay of claim 13, wherein the averager is a passive voltage averager.

15. The RM electronic overload relay of claim 11, wherein the variable trip current generator is a potentiometer being coupled across the reference voltage.

16. The RM electronic overload relay of claim 11, wherein each of the RM current sensor for each branch is calibrated to produce a maximum sensed load current output value when sourcing an AC current into the main path having a magnitude equal to the maximum magnitude of the range of FLC.

17. The RM electronic overload relay of claim 11, wherein the RM current sensor assemblies are calibrated to produce a maximum sensed load current output when sourcing an AC current into the main path having a magnitude equal to the maximum magnitude of the range of FLC times 1.10.

18. The RM electronic overload relay of claim 17, wherein the predetermined reference voltage of the settable trip current is equal to the maximum sensed load current output.

19. The RM electronic overload relay of claim 18, wherein the maximum sensed load current output value is 5 volts.
